(19) United States
(12) Patent Application Publication
(10) Pub. No.: US 2025/0185496 A1
(43) Pub. Date: Jun. 5, 2025

(54) METHOD FOR MANUFACTURING ORGANIC LAYER COMPOSITION AND METHOD FOR MANUFACTURING DISPLAY DEVICE

(71) Applicant: Samsung Display Co., Ltd., Yongin-Si (KR)

(72) Inventor: Se Joon OH, Yongin-si (KR)

(21) Appl. No.: 18/747,441

(22) Filed: Jun. 19, 2024

(30) Foreign Application Priority Data
Dec. 1, 2023 (KR) 10-2023-0171972

(51) Int. Cl. H10K 71/13; H10K 71/40; H10K 71/60; H10K 85/10

(52) U.S. Cl. CPC H10K 71/135; H10K 71/40; H10K 71/611; H10K 85/111

(57) ABSTRACT

A method for manufacturing an organic layer composition and a method for manufacturing a display device are provided. The method for manufacturing an organic layer composition, the method comprises preparing a raw material, forming an organic layer composition by placing the raw material in a manufacturing device and stirring the raw material, and cooling the organic layer composition at a cooling rate of 0.37 to 0.44° C./min.

### CROSS-REFERENCE TO RELATED APPLICATION

This application claims priority from Korean Patent Application No. 10-2023-0171972 filed on Dec. 1, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a method for manufacturing an organic layer composition and a method for manufacturing a display device.

### 2. Description of the Related Art

With the development of information society, the demand for a display device for displaying an image has been increasing. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. The light emitting display device includes an organic light emitting display device including an organic light emitting element, an inorganic light emitting display device including an inorganic light emitting element such as an inorganic semiconductor, and a subminiature light emitting display device including a subminiature light emitting element.

The organic light emitting element may include two opposing electrodes and a light emitting layer interposed therebetween. The light emitting layer receives electrons and holes from the two electrodes and recombines the electronic and the holes to generate excitons, and the generated excitons change from an excited state to a ground state, thereby emitting light.

The organic light emitting display device including the organic light emitting element may be configured to havelight weight and thin shape with low power consumption because a light source such as a backlight unit is not required. Organic light emitting display device has also attracted attention as a next-generation display device because of having high-quality characteristics such as a wide viewing angle, high luminance and contrast, and a fast response speed.

### SUMMARY

Aspects of the present disclosure provide a method for manufacturing a display device that may improve application defects of an organic layer by controlling a cooling rate of the organic layer of a thin film encapsulation layer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a method for manufacturing an organic layer composition, the method comprises preparing a raw material, forming an organic layer composition by placing the raw material in a manufacturing device and stirring the raw material, and cooling the organic layer composition at a cooling rate of 0.37 to 0.44° C./min.

In an embodiment, the raw material includes a monomer, an initiator and a solvent.

In an embodiment, the monomer is an acrylic or epoxy monomer.

In an embodiment, the initiator includes a photo-initiator or a combination of a photo-initiator and a thermal initiator.

In an embodiment, the manufacturing device includes a tank containing the raw material, a flow path surrounding the tank, an inlet introducing coolant into the flow path, an outlet through which the coolant is discharged from the flow path, a thermometer disposed outside the tank and sensing a temperature within the tank, and a controller disposed outside the tank.

In an embodiment, the inlet is disposed at one end of the flow path, and the outlet is disposed at the other end of the flow path.

In an embodiment, the controller receives the temperature from the thermometer and controls a temperature and a flow rate of the coolant.

In an embodiment, the controller is a Proportional Integral Derivative (PDI) controller.

In an embodiment, the organic layer composition is cooled to 25° C.

According to an aspect of the present disclosure, a method for manufacturing a display device, the method comprises forming a light emitting element layer including a light emitting element on a substrate, forming a lower inorganic layer on the light emitting element layer, forming an organic layer by applying an organic layer composition on the lower inorganic layer, and forming an upper inorganic layer on the organic layer, wherein the organic layer composition is manufactured by preparing a raw material, forming an organic layer composition by inputting the raw material to a manufacturing device and stirring the raw material, and cooling the organic layer composition at a cooling rate of 0.37 to 0.44° C./min.

In an embodiment, the forming of the light emitting element layer includes forming a pixel electrode on the substrate, forming a pixel defining film covering an edge of the pixel electrode, forming a light emitting layer on the pixel electrode and the pixel defining film, and forming a common electrode on the light emitting layer.

In an embodiment, the lower inorganic layer is formed on the common electrode of the light emitting element layer.

In an embodiment, the organic layer composition is applied by an inkjet printing method.

In an embodiment, the raw material includes a monomer, an initiator and a solvent.

In an embodiment, the monomer is an acrylic or epoxy monomer.

In an embodiment, the manufacturing device includes a tank containing the raw material, a flow path surrounding the tank, an inlet introducing coolant into the flow path, an outlet through which the coolant is discharged from the flow path, a thermometer disposed outside the tank and sensing a temperature within the tank, and a controller disposed outside the tank.

In an embodiment, the inlet is disposed at one end of the flow path, and the outlet is disposed at the other end of the flow path.

In an embodiment, the controller receives the temperature from the thermometer and controls a temperature and a flow rate of the coolant.

In an embodiment, the controller is a Proportional Integral Derivative (PDI) controller.

In an embodiment, the organic layer composition is cooled to 25° C.

According to the method for manufacturing the composition of the organic layer and the method for manufacturing the display device according to the embodiment, a decrease in the spreadability and poor impact of the organic layer composition during inkjet printing may be prevented by cooling the organic layer composition at a cooling rate in the range of 0.37° C./min to 0.44° C./min, thereby improving the quality of the display device.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to an embodiment;

FIG. 2 is a schematic layout view illustrating lines included in the display device according to an embodiment;

FIG. 3 is an equivalent circuit diagram of one sub-pixel according to an embodiment;

FIG. 4 is a cross-sectional view schematically illustrating the display device according to an embodiment;

FIG. 5 is a cross-sectional view schematically illustrating a display area of the display device according to an embodiment;

FIG. 6 is a cross-sectional view schematically illustrating the display device according to an embodiment;

FIG. 7 is a flowchart schematically illustrating a method for manufacturing an organic layer composition according to an embodiment;

FIG. 8 is a view schematically illustrating a device for manufacturing an organic layer composition;

FIG. 9 is a graph illustrating a temperature of a tank of the manufacturing device over time; and

FIGS. 10 to 12 are cross-sectional views illustrating a method for manufacturing a display device according to an embodiment.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when a layer is referred to as being “on” another layer or substrate, it can be directly on the other layer or substrate, or intervening layers may be present. The same reference numbers indicate the same components throughout the specification.

It will be understood that, although the terms “first,” “second,” etc. may be used herein to describe various elements, these elements should not be limited to any specific order by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined, in part or in whole, and technically various interlocking and driving are possible. Each embodiment may be implemented independently of each other or may be implemented together in an association.

Hereinafter, embodiments of the present disclosure will be described with reference to the accompanying drawings.

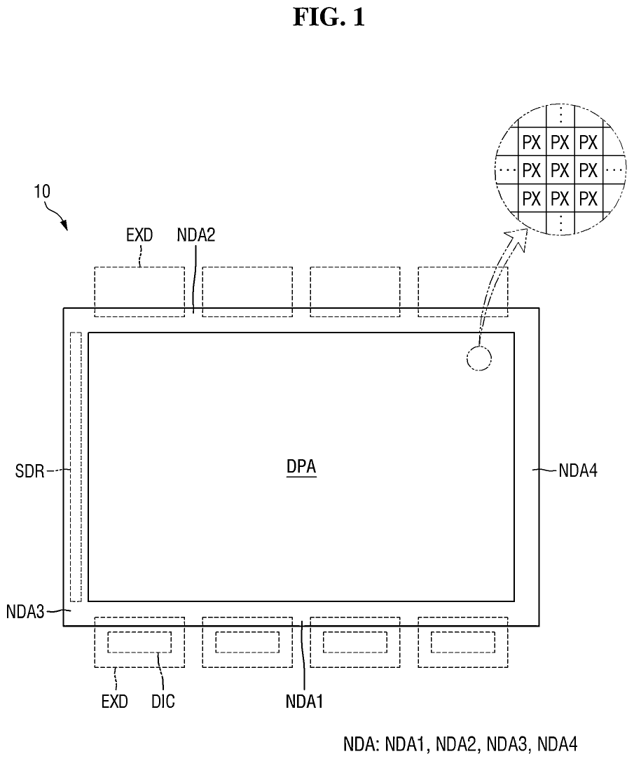

FIG. 1 is a plan view of a display device according to an embodiment.

Referring to FIG. 1, a display device 10 according to an embodiment may be applied to smartphones, mobile phones, tablet personal computers (PCs), personal digital assistants (PDAs), portable multimedia players (PMPs), televisions, game machines, wrist watch-type electronic devices, head-mounted displays, monitors of personal computers, laptop computers, car navigation systems, vehicle instrument boards, digital cameras, camcorders, external billboards, electric signs, medical devices, inspection devices, various home appliances such as refrigerators and washing machines, or Internet of Things (IoT) devices. In the present specification, a television (TV) will be described as an example of the display device 10, and the TV may have high resolution or ultra-high resolution such as high definition (HD), ultra-high definition (UHD), 4K, or 8K.

In addition, the display device 10 according to an embodiment may be variously classified according to a display method. For example, the classification of the display device 10 may include an organic light emitting display (OLED), an inorganic light emitting display (inorganic EL), a quantum dot light emitting display (QED), a micro LED, a nano LED, a plasma display panel (PDP), a field emission display (FED), a cathode ray tube display (CRT), a liquid crystal display (LCD), an electrophoretic display (EPD), and the like. In the following, an organic light emitting display device and an inorganic light emitting display device will be described as an example of the display device 10, and unless a special distinction is required, an organic light emitting display device applied to an embodiment will be simply abbreviated as a display device. However, an embodiment is not limited to the organic light emitting display device or the inorganic light emitting display device, and other display devices listed above or known in the art may also be applied within the scope of sharing technical ideas.

The display device 10 according to an embodiment may have a square shape in plan view, for example, a rectangular shape. When the display device 10 is a television, the display device 10 is disposed so that a long side thereof is positioned in a horizontal direction. However, the present disclosure is not limited thereto, and the long side of the display device 10 may be positioned in a vertical direction, and the display device 10 may be rotatably installed, so that the long side of the display device 10 may also be variably positioned in the horizontal or vertical direction.

The display device 10 may include a display area DPA and a non-display area NDA. The display area DPA may be an active area in which an image is displayed. The display area DPA may have a rectangular shape in plan view, similar to the overall shape of the display device 10, but is not limited thereto.

The display area DPA may include a plurality of pixels PX. The plurality of pixels PX may be arranged in a matrix. The shape of each pixel PX may be rectangular or square in plan view, but is not limited thereto, and may also be a rhombic shape of which each side is inclined with respect to a direction of one side of the display device 10. The plurality of pixels PX may include multiple color pixels PX. For example, the plurality of pixels PX may include, but are not limited to, a first color pixel PX of red, a second color pixel PX of green, and a third color pixel PX of blue. Each color pixel PX may be alternately arranged in a stripe type or PenTile™ type.

The non-display area NDA may be disposed around the display area DPA. The non-display area NDA may entirely or partially surround the display area DPA. The display area DPA may have a rectangular shape, and the non-display area NDA may be disposed adjacent to four sides of the display area DPA. The non-display area NDA may constitute a bezel of the display device 10.

A driving circuit or a driving element for driving the display area DPA may be disposed in the non-display area NDA. In an embodiment, pad portions may be provided on a display substrate of the display device 10 in a first non-display area NDA1 disposed adjacent to a first long side (lower side in FIG. 1) of the display device 10 and a second non-display area NDA2 disposed adjacent to a second long side (upper side in FIG. 1) of the display device 10, and external devices EXD may be mounted on pad electrodes of the pad portions. Examples of the external devices EXD may include a connection film, a printed circuit board, a driving chip (DIC), a connector, a line connection film, and the like. A scan driver SDR and the like formed directly on the display substrate of the display device 10 may be disposed in a third non-display area NDA3 disposed adjacent to a first short side (left side in FIG. 1) of the display device 10. However, the present disclosure is not limited thereto, and the scan driver SDR may also be disposed on a second short side (right side in FIG. 1) of the display device 10.

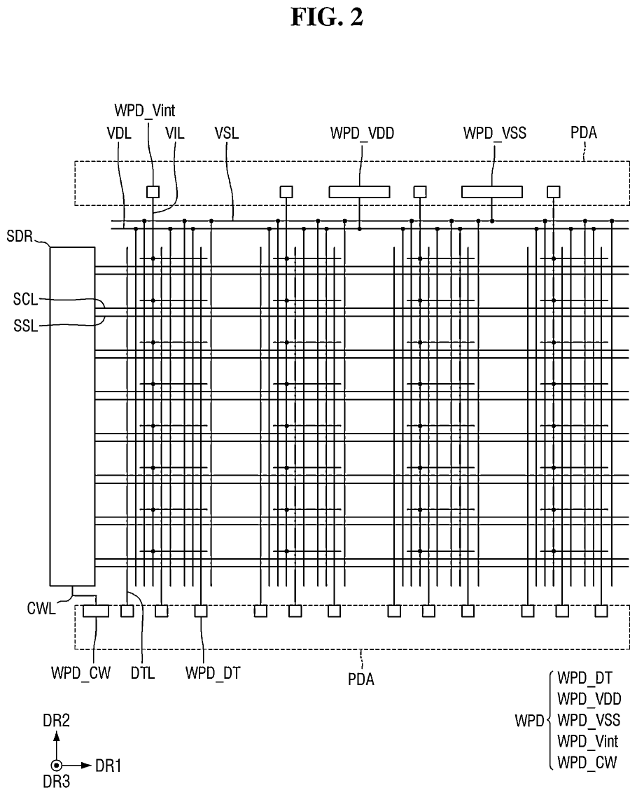

FIG. 2 is a schematic layout view illustrating lines included in the display device according to an embodiment.

Referring to FIG. 2, the display device 10 may include a plurality of lines. The plurality of lines may include a scan line SCL, a sensing line SSL, a data line DTL, an initialization voltage line VIL, a first voltage line VDL, and a second voltage line VSL. In addition, although not illustrated in the drawing, other lines may be further disposed in the display device 10.

The scan line SCL and the sensing line SSL may extend in a first direction DR1. The scan line SCL and the sensing line SSL may be connected to the scan driver SDR. The scan driver SDR may include a driving circuit. The scan driver SDR may be disposed on one side of the display area DPA in the first direction DR1, but is not limited thereto. The scan driver SDR may be connected to a signal connection line CWL, and at least one end of the signal connection line CWL may be connected to an external device by forming a pad WPD_CW on a pad area PDA of the non-display area.

Meanwhile, in the present specification, “connection” may mean that any one member is connected to another member through mutual physical contact, as well as that any one member is connected to another member through a third member. In addition, it may be understood that any one portion and another portion as one integrated member are interconnected due to the integrated member. Furthermore, the connection between any one member and another member may be interpreted as including an electrical connection through a third intervening member in addition to a connection through direct contact between two members.

The data line DTL and the initialization voltage line VIL may extend in a second direction DR2 intersecting the first direction DR1. The initialization voltage line VIL may further include a portion extending in the second direction DR2 and a portion branching therefrom in the first direction DR1. The first voltage line VDL and the second voltage line VSL may also include portions extending in the second direction DR2 and portions connected thereto and extending in the first direction DR1. The first voltage line VDL and the second voltage line VSL may have a mesh structure, but are not limited thereto. Although not illustrated in the drawing, each of the pixels PX of the display device 10 may be connected to one or more data lines DTL, initialization voltage lines VIL, first voltage lines VDL, and second voltage lines VSL.

The data line DTL, the initialization voltage line VIL, the first voltage line VDL, and the second voltage line VSL may be electrically connected to at least one line pad WPD. Each line pad WPD may be disposed in the pad area PDA. In an embodiment, a line pad WPD_DT (hereinafter, referred to as ‘data pad’) of the data line DTL may be disposed in a pad area PDA on one side of the display area DPA in the second direction DR2, and a line pad WPD_Vint (hereinafter, “initialization voltage pad”) of the initialization voltage line VIL, a line pad WPD_VDD (hereinafter, a “first power pad”) of the first voltage line VDL, and a line pad WPD_VSS (hereinafter, “second power pad”) of the second voltage line VSL may be disposed in a pad area PDA positioned on the other side of the display area DPA in the second direction DR2. In another embodiment, the data pad WPD_DT, the initialization voltage pad WPD_Vint, the first power pad WPD_VDD, and the second power pad WPD_VSS may all be disposed in the same area, for example, in the non-display area NDA positioned on an upper side of the display area DPA. The external device EXD may be mounted on the line pad WPD. The external device EXD may be mounted on the line pad WPD through an anisotropic conductive film, ultrasonic bonding, or the like.

Each pixel PX or sub-pixel PXn (n is an integer of 1 to 3) of the display device 10 includes a pixel driving circuit. The above-described lines may apply a driving signal to each pixel driving circuit while passing through each pixel PX or passing around each pixel PX. The pixel driving circuit may include a transistor and a capacitor. The numbers of transistors and capacitors in each pixel driving circuit may be variously changed. According to an embodiment, each sub-pixel SPXn of the display device 10 may have a 3TIC structure in which the pixel driving circuit includes three transistors and one capacitor. Hereinafter, the pixel driving circuit will be described using the 3TIC structure as an example, but the present disclosure is not limited thereto, and various other modified pixel PX structures such as a 2TIC structure, a 7TIC structure, and a 6TIC structure may also be applied.

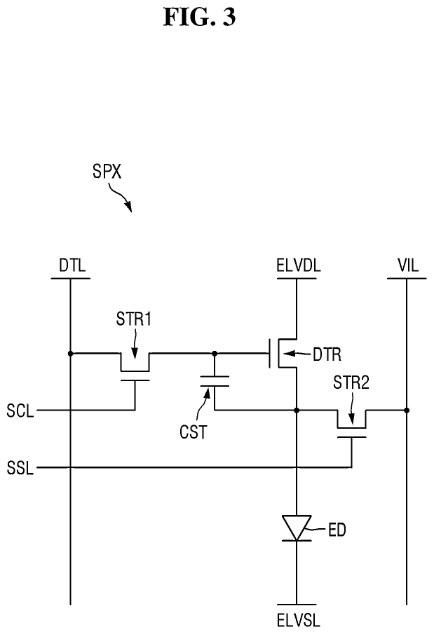

FIG. 3 is an equivalent circuit diagram of one sub-pixel according to an embodiment.

Referring to FIG. 3, each sub-pixel SPX of the display device 10 according to an embodiment includes three transistors DTR, STR1, and STR2 and one storage capacitor CST, in addition to a light emitting element ED.

The light emitting element ED emits light according to a current supplied through a driving transistor DTR. The light emitting element ED may be implemented as an inorganic light emitting diode, an organic light emitting diode, a micro light emitting diode, a nano light emitting diode, or the like.

A first electrode (i.e., an anode electrode) of the light emitting element ED may be connected to a source electrode of the driving transistor DTR, and a second electrode (i.e., a cathode electrode) of the light emitting element ED may be connected to a second power line ELVSL to which a low potential voltage (second power voltage) lower than a high potential voltage (first power voltage) of a first power line ELVDL is supplied.

The driving transistor DTR adjusts a current flowing from the first power line ELVDL to which the first power is supplied to the light emitting element ED according to a voltage difference between a gate electrode and the source electrode. The gate electrode of the driving transistor DTR may be connected to a first electrode of a first transistor STR1, the source electrode of the driving transistor DTR may be connected to the first electrode of the light emitting element ED, and a drain electrode of the driving transistor DTR may be connected to the first power line ELVDL to which the first power voltage is applied.

The first transistor STR1 is turned on by a scan signal of the scan line SCL and connects the data line DTL to the gate electrode of the driving transistor DTR. A gate electrode of the first transistor STR1 may be connected to the scan line SCL, the first electrode of the first transistor STR1 may be connected to the gate electrode of the driving transistor DTR, and a second electrode of the first transistor STR1 may be connected to the data line DTL.

A second transistor STR2 is turned on by a sensing signal of the sensing signal line SSL and connects the initialization voltage line VIL to the source electrode of the driving transistor DTR. A gate electrode of the second transistor STR2 may be connected to the sensing signal line SSL, a first electrode of the second transistor STR2 may be connected to the initialization voltage line VIL, and a second electrode of the second transistor STR2 may be connected to the source electrode of the driving transistor DTR.

In an embodiment, the first electrode of each of the first and second transistors STR1 and STR2 may be a source electrode, and the second electrode of each of the first and second transistors STR1 and STR2 may be a drain electrode, but the present disclosure is not limited thereto.

A capacitor CST is formed between the gate electrode and the source electrode of the driving transistor DTR. The storage capacitor CST stores a difference voltage between a gate voltage and a source voltage of the driving transistor DTR.

The driving transistor DTR and the first and second switching transistors STR1 and STR2 may be formed as thin film transistors. In addition, it is mainly described in FIG. 3 that the driving transistor DTR and the first and second transistors STR1 and STR2 are N-type metal oxide semiconductor field effect transistors (MOSFETs), but the present disclosure is not limited thereto. That is, the driving transistor DTR and the first and second transistors STR1 and STR2 may be P-type MOSFETs, or some thereof may be N-type MOSFETs and others thereof may be P-type MOSFETs.

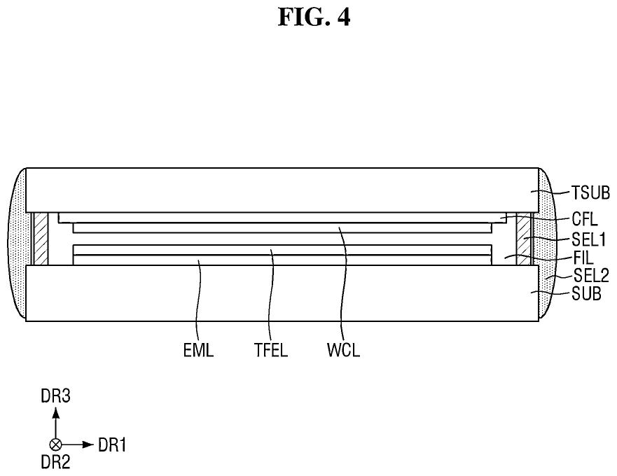

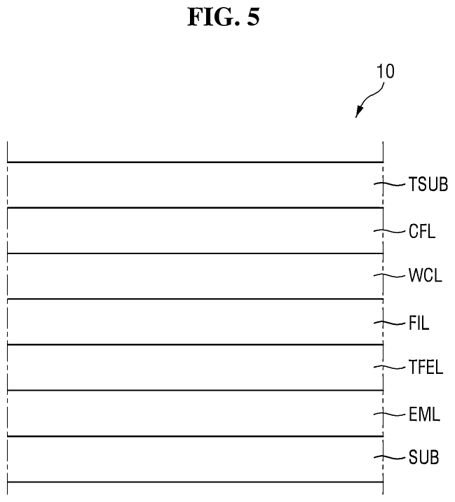

FIG. 4 is a cross-sectional view schematically illustrating the display device according to an embodiment. FIG. 5 is a cross-sectional view schematically illustrating a display area of the display device according to an embodiment.

Referring to FIGS. 4 and 5, the display device 10 according to an embodiment may include a substrate SUB, a light emitting element layer EML, a thin film encapsulation layer TFEL, a filling layer FIL, a wavelength conversion layer WCL, a color filter layer CFL, a counter substrate TSUB, a first coupling member SEL1, and a second coupling member SEL2.

The substrate SUB may be an insulating substrate. The substrate SUB may include a transparent material. For example, the substrate SUB may include a transparent insulating material such as glass or quartz. The substrate SUB may be a rigid substrate. In addition, the substrate SUB is not limited thereto, and may also include plastic such as polyimide and may also have flexible properties capable of being curved, bent, folded, or rolled.

The light emitting element layer EML may be disposed on the substrate SUB. The light emitting element layer EML may include a plurality of switching elements and a plurality of light emitting elements ED disposed in each sub-pixel. The plurality of switching elements may drive the plurality of light emitting elements ED to emit light from the plurality of light emitting elements ED.

The thin film encapsulation layer TFEL may be disposed on the light emitting element layer EML. The thin film encapsulation layer TFEL may include an organic layer disposed between a plurality of inorganic layers, thereby protecting the light emitting element layer EML from external moisture and oxygen.

A counter substrate TSUB opposite to the substrate SUB may be disposed. The counter substrate TSUB may encapsulate the light emitting element layer EML together with the substrate SUB. The counter substrate TSUB may include a transparent material. For example, the counter substrate TSUB may include a transparent insulating material such as glass or quartz.

A color filter layer CFL may be disposed on one surface of the counter substrate TSUB. The color filter layer CFL may filter light incident from the outside to reduce reflection of external light and improve color characteristics of light emitted through the wavelength conversion layer WCL.

The wavelength conversion layer WCL may be disposed on one surface of the color filter layer CFL. The wavelength conversion layer WCL may convert a wavelength of light emitted from the light emitting element layer EML to emit red light, green light, and blue light.

A filling layer FIL may be disposed between the substrate SUB and the counter substrate TSUB. The filling layer FIL may be filled between the substrate SUB and the counter substrate TSUB to protect the display area of the display device 10.

The substrate SUB and the counter substrate TSUB may be coupled to each other by the first coupling member SEL1. The first coupling member SEL1 may seal the light emitting element layer EML by coupling the substrate SUB and the counter substrate TSUB to each other. The first coupling member SEL1 may be disposed in the non-display area to surround the display area of the display device 10.

A second coupling member SEL2 may be disposed on side surfaces of the substrate SUB and the counter substrate TSUB. The second coupling member SEL2 may seal a side surface of the display device 10 and prevent moisture infiltration.

Hereinafter, the configurations of the display device according to an embodiment will be described in detail with reference to other drawings.

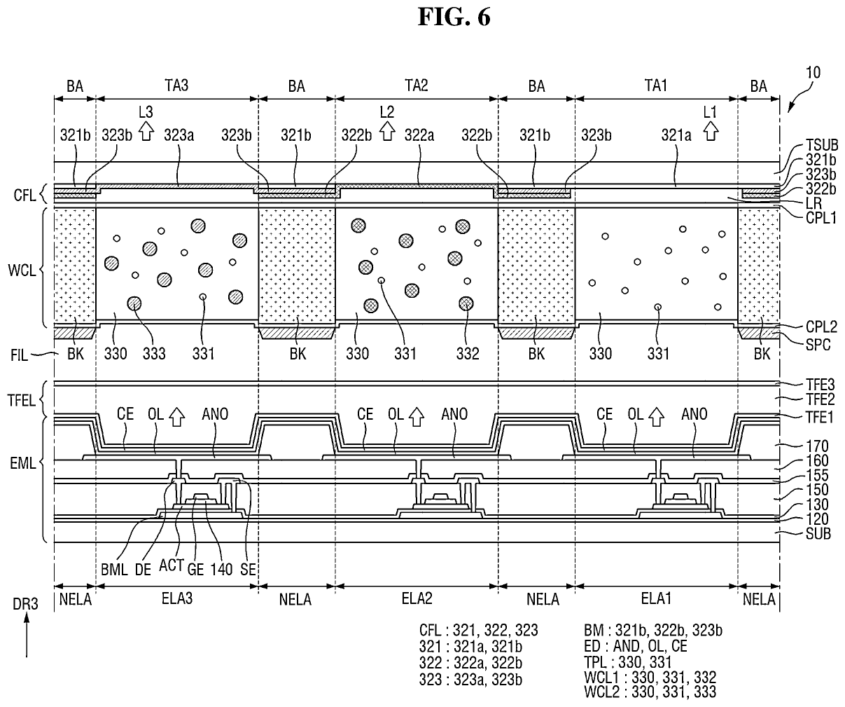

FIG. 6 is a cross-sectional view schematically illustrating the display device according to an embodiment. FIG. 6 illustrates a portion of the display area of the display device.

Referring to FIG. 6 and FIG. 5, the light emitting element layer EML may be disposed on the substrate SUB. The light emitting element layer EML may include a buffer layer 120, a lower metal layer BML, a first insulating layer 130, a semiconductor layer ACT, a gate electrode GE, a gate insulating layer GI, a second insulating layer 150, a source electrode SE, a drain electrode DE, a third insulating layer 155, a fourth insulating layer 160, a light emitting element ED, and a pixel defining film 170.

The buffer layer 120 may be disposed on the substrate SUB. The buffer layer 120 may serve to block foreign substances or moisture from permeating into an element disposed on the buffer layer 120 through the substrate SUB.

The buffer layer 120 may include an inorganic material such as SiO₂, SiNx, or SiON, and may be formed as a single layer or a multi-layer, but is not limited thereto.

The lower metal layer BML may be disposed on the buffer layer 120. The lower metal layer BML may block external light or light emitted from a light emitting element to be described later from being introduced into the semiconductor layer ACT. Accordingly, it is possible to reduce or prevent leakage current caused by light in a thin film transistor, which will be described later.

The lower metal layer BML may be formed of a material that blocks light and has conductivity. In some embodiments, the lower metal layer BML may include a single material among metals such as silver (Ag), nickel (Ni), gold (Au), platinum (Pt), aluminum (Al), copper (Cu), molybdenum (Mo), titanium (Ti), and neodymium (Nd), or an alloy thereof. In some embodiments, the lower metal layer BML may have a single layer or a multi-layer structure. For example, when the lower metal layer BML has the multi-layer structure, the lower metal layer BML may be a stacked structure of titanium (Ti)/copper (Cu)/indium tin oxide (ITO) or a stacked structure of titanium (Ti)/copper (Cu)/aluminum oxide (Al₂O₃), but is not limited thereto.

In some embodiments, the lower metal layer BML may be provided in plural to correspond to each semiconductor layer ACT and may overlap the semiconductor layer ACT. In some embodiments, a width of the lower metal layer BML may be wider than a width of the semiconductor layer ACT.

In some embodiments, the lower metal layer BML may also be a portion of a data line, a power supply line, or a wiring electrically connecting a thin film transistor (not illustrated) and a thin film transistor (GE, ACT, DE, and SE in FIG. 6) illustrated in the drawing to each other. In some embodiments, the lower metal layer BML may be made of a material having a lower resistance than the source electrode SE and the drain electrode DE.

The first insulating layer 130 may be disposed on the lower metal layer BML. The first insulating layer 130 may serve to electrically insulate the lower metal layer BML and the semiconductor layer ACT from each other. The first insulating layer 130 may cover the lower metal layer BML.

The first insulating layer 130 may include an inorganic material such as SiO₂, SiNx, SiON, Al₂O₃, TiO₂, Ta₂O, HfO₂, or ZrO₂, but is not limited thereto.

The semiconductor layer ACT may be disposed on the first insulating layer 130. The semiconductor layer ACT may be disposed to correspond to the first light emitting area ELA1, the second light emitting area ELA2, and the third light emitting area ELA3 in the display area DPA, respectively. In addition, the semiconductor layer ACT may be disposed to overlap each lower metal layer BML, thereby suppressing generation of a photocurrent in the semiconductor layer ACT.

The semiconductor layer ACT may include an oxide semiconductor. In some embodiments, the semiconductor layer ACT may be formed of Zn oxide-based materials such as Zn oxide, In—Zn oxide, and Ga—In—Zn oxide, and may be an IGZO (In—Ga—Zn—O) semiconductor containing metals such as indium (In) and gallium (Ga) in ZnO, but is not limited thereto. For example, the semiconductor layer ACT may include amorphous silicon or polysilicon.

The gate electrode GE may be disposed on the semiconductor layer ACT. The gate electrode GE may be disposed to overlap the semiconductor layer ACT in the display area DPA. In some embodiments, a width of the gate electrode GE may be narrower than a width of the semiconductor layer ACT, but is not limited thereto.

The gate electrode GE may include one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), in consideration of adhesiveness with adjacent layers, surface flatness of stacked layers, processability, and the like, and may be formed of a single layer or a multi-layer, but is not limited thereto.

The gate insulating layer 140 may be disposed between the semiconductor layer ACT and the gate electrode GE. The gate insulating layer 140 may serve to insulate the semiconductor layer ACT and the gate electrode GE from each other. In some embodiments, the gate insulating layer 140 is not formed of one layer disposed on one side of a first substrate 110 in the third direction DR3, but has a partially patterned shape, and a width of the gate insulating layer 140 may be narrower than the width of the semiconductor layer ACT and may be greater than the width of the gate electrode GE, but is not limited thereto.

The gate insulating layer 140 may include an inorganic material. For example, the gate insulating layer 140 may include the inorganic material exemplified in the description of the first insulating layer 130.

The second insulating layer 150 may be disposed on the gate insulating layer 140 and cover the semiconductor layer ACT and the gate electrode GE. In some embodiments, the second insulating layer 150 may function as a planarization film that provides a flat surface.

The second insulating layer 150 may include an organic material. In some embodiments, the second insulating layer 150 may include at least one of photo acryl (PAC), polystyrene, polymethyl methacrylate (PMMA), polyacrylonitrile (PAN), polyamide, polyimide, polyarylether, heterocyclic polymer, parylene, fluorine-based polymer, epoxy resin, benzocyclobutene series resin, siloxane series resin, and silane resin, but is not limited thereto.

In some embodiments, the second insulating layer 150 may include an inorganic material. For example, the second insulating layer 150 may include the inorganic material exemplified in the description of the first insulating layer 130.

The source electrode SE and the drain electrode DE may be spaced apart from each other and disposed on the second insulating layer 150. The source electrode SE and the drain electrode DE may each be connected to the semiconductor layer ACT through a contact hole penetrating through the second insulating layer 150. The source electrode SE may penetrate through not only the second insulating layer 150 but also the first insulating layer 130 and be connected to the lower metal layer BML. When the lower metal layer BML is a portion of a line that transmits signals or voltages, the source electrode SE may be connected to and electrically coupled to the lower metal layer BML to receive the voltage and the like provided to the line. Alternatively, when the lower metal layer BML is a floating pattern instead of a separate line, the voltage and the like provided to the source electrode SE may be transmitted to the lower metal layer BML.

The source electrode SE and the drain electrode DE may include aluminum (Al), copper (Cu), titanium (Ti), or the like, and may be formed of a multi-layer or a single layer. In some embodiments, the source electrode SE and the drain electrode DE may have a multi-layer structure of Ti/Al/Ti, but are not limited thereto.

The semiconductor layer ACT, the gate electrode GE, the source electrode SE, and the drain electrode DE described above may form a thin film transistor, which is a switching element. In some embodiments, the thin film transistor may be positioned in the first light emitting area ELA1, the second light emitting area ELA2, and the third light emitting area ELA3, respectively. In some embodiments, a portion of the thin film transistor may also be positioned in the non-light emitting area NELA.

The third insulating layer 155 may be disposed on the second insulating layer 150 to cover the thin film transistor. In some embodiments, the third insulating layer 155 may be a passivation layer.

In some embodiments, the third insulating layer 155 may include an inorganic material. For example, the third insulating layer 155 may include the inorganic material exemplified in the description of the first insulating layer 130.

The fourth insulating layer 160 may be disposed on the third insulating layer 155 to cover the third insulating layer 155. In some embodiments, the fourth insulating layer 160 may be a planarization film.

The fourth insulating layer 160 may be formed of an organic material. In some embodiments, the fourth insulating layer 160 may include acrylic resin, epoxy resin, imide resin, ester resin, etc., or may include a photosensitive organic material, but is not limited thereto.

Anode electrodes ANO may be positioned on the fourth insulating layer 160 in the display area DPA.

The anode electrodes ANO may be present in each of the first light emitting area ELA1, the second light emitting area ELA2, and the third light emitting area ELA3, and at least some thereof may also extend to the non-light emitting area NELA. The anode electrodes ANO may be connected to the drain electrode DE of the thin film transistor.

In some embodiments, the anode electrode ANO may be a reflective electrode. In this case, the anode electrode ANO may be a metal layer including metals such as Ag, Mg, Al, Pt, Pd, Au, Ni, Nd, Ir, and Cr. In another embodiment, the anode electrode ANO may further include a metal oxide layer stacked on the metal layer. In an embodiment, the anode electrode ANO may have a multi-layer structure, for example, a two-layer structure such as ITO/Ag, Ag/ITO, ITO/Mg, and ITO/MgF, or a three-layer structure such as ITO/Ag/ITO.

The pixel defining film 170 may be disposed on the anode electrodes ANO. The pixel defining film 170 may define a first light emitting area ELA1, a second light emitting area ELA2, and a third light emitting area ELA3, respectively, as openings exposing the anode electrodes ANO.

The pixel defining film 170 may overlap a light blocking area BA of a color filter layer CFL, which will be described later, in the third direction DR3. In addition, the pixel defining film 170 may also overlap a bank BK, which will be described later, in the third direction DR3.

The pixel defining film 170 may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB), but is not limited thereto.

A light emitting layer OL may be disposed on the anode electrode ANO. In some embodiments, the light emitting layer OL may have a shape of a continuous film formed over the plurality of light emitting areas and the non-light emitting area NELA. In some embodiments, the light emitting layer OL may be positioned only within the display area DPA, but is not limited thereto. For example, a portion of the light emitting layer OL may be further positioned in the non-display area NDA.

In some embodiments, the light emitting layer OL may include an organic layer including an organic material. The organic layer may include an organic light emitting layer, and may further include a hole injection/transporting layer and/or an electron injection/transporting layer as an auxiliary layer to assist light emission in some cases.

In some embodiments, when the display device 10 is a micro LED display device or a nano LED display device, the light emitting layer OL may also include an inorganic material such as an inorganic semiconductor.

A cathode electrode CE may be disposed on the light emitting layer OL. In some embodiments, the cathode electrode CE may be disposed on the light emitting layer OL and have a shape of a continuous film formed over the plurality of light emitting areas ELA1, ELA2, and ELA3 and the non-light emitting area NELA. In other words, the cathode electrode CE may completely cover the light emitting layer OL.

The cathode electrode CE may have semi-permeability or permeability. When the cathode electrode CE has a thickness of several tens to several hundreds of angstroms, the cathode electrode CE may have semi-permeability. In some embodiments, when the cathode electrode CE has the semi-permeability, the cathode electrode CE may include Ag, Mg, Cu, Al, Pt, Pd, Au, Ni, Nd, Ir, Cr, Li, Ca, LiF/Ca, LiF/Al, Mo, Ti, or a compound or mixture thereof, for example, a mixture of Ag and Mg. Meanwhile, the cathode electrode CE may include transparent conductive oxide and may have permeability. In some embodiments, when the cathode electrode CE has the permeability, the cathode electrode CE may include tungsten oxide (WxOx), titanium oxide (TiO₂), indium tin oxide (ITO), indium zinc oxide (IZO), zinc oxide (ZnO), indium tin zinc oxide (ITZO), magnesium oxide (MgO), or the like.

The anode electrode ANO, the light emitting layer OL, and the cathode electrode CE may form light emitting elements ED. For example, the anode electrode ANO, the light emitting layer OL, and the cathode electrode CE in the first light emitting area ELA1 may form a first light emitting element, the anode electrode ANO, the light emitting layer OL, and the cathode electrode CE in the second light emitting area ELA2 may form a second light emitting element, and the anode electrode ANO, the light emitting layer OL, and the cathode electrode CE in the third light emitting area ELA3 may form a third light emitting element. The first light emitting element, the second light emitting element, and the third light emitting element may each emit light. The emitted light from each light emitting element ED may have a peak wavelength of at least 440 nm and no more than 480 nm. In one embodiment, the light emitted by the first, second, and third light emitting elements may be blue light.

Meanwhile, the thin film encapsulation layer TFEL may be disposed on the light emitting element layer EML. The thin film encapsulation layer TFEL may be disposed on the cathode electrode CE. The thin film encapsulation layer TFEL may serve to protect components positioned below the thin film encapsulation layer TFEL from external substances such as moisture. The thin film encapsulation layer TFEL may be commonly disposed in the first light emitting area ELA1, the second light emitting area ELA2, the third light emitting area ELA3, and the non-light emitting area NELA.

The thin film encapsulation layer TFEL may include a lower inorganic layer TFE1, an organic layer TFE2, and an upper inorganic layer TFE3 sequentially stacked on a first capping layer CPL1.

The lower inorganic layer TFE1 may completely cover the cathode electrode CE in the display area DPA and cover the first light emitting element, the second light emitting element, and the third light emitting element. The organic layer TFE2 may be disposed on the lower inorganic layer TFEL and cover the first light emitting element, the second light emitting element, and the third light emitting element. The upper inorganic layer TFE3 may be disposed on the organic layer TFE2 and completely cover the organic layer TFE2.

In some embodiments, each of the lower inorganic layer TFE1 and the upper inorganic layer TFE3 may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, or the like, but is not limited thereto.

In some embodiments, the organic layer TFE2 may be made of an acrylic resin, a methacrylic resin, polyisoprene, a vinyl resin, an epoxy resin, a urethane resin, a cellulose resin, a perylene resin, or the like, but is not limited thereto.

FIG. 6 depicts a counter substrate TSUB may be disposed on the substrate SUB on which the light emitting element layer EML and the thin film encapsulation layer TFEL are disposed. A color filter layer CFL and a wavelength conversion layer WCL disposed on one surface of the color filter layer CFL may be disposed on one surface of the counter substrate TSUB. In addition, the display device 10 may include a low refractive layer LR and a first capping layer CPL1 disposed between the color filter layer CFL and the wavelength conversion layer WCL, and may include a spacer layer SPC disposed on one surface of the wavelength conversion layer WCL.

The color filter layer CFL may be disposed on the other side of the counter substrate TSUB in the third direction DR3, that is, between the counter substrate TSUB and the substrate SUB. The color filter layer CFL may include a filtering pattern area and a light blocking pattern portion BM. The light blocking pattern portion BM may surround the filtering pattern area. The filtering pattern of the color filter layer CFL may define a light transmitting area, and the light blocking pattern portion BM may define a light blocking area BA.

The color filter layer CFL may include a first color filter 321, a second color filter 322, and a third color filter 323 as illustrated in FIG. 6. The first color filter 321 may absorb substantially all of second light and third light but not the first light, the second color filter 322 may absorb substantially all of the first light and the third light but not the second light, and the third color filter 323 may absorb substantially all of the first light and the second light but not the third light. In other words, the first color filter 321 may transmit the first light, the second color filter 322 may transmit the second light, and the third color filter 323 may transmit the third light.

In some embodiments, the first color filter 321 may be a blue color filter and may include a blue colorant. In the present specification, a colorant could be a dye, a pigment, or a combination. The first color filter 321 may include a base resin, and the blue colorant may be dispersed in the base resin. In some embodiments, the second color filter 322 may be a green color filter and may include a green colorant. The second color filter 322 may include a base resin, and the green colorant may be dispersed in the base resin. In some embodiments, the third color filter 323 may be a red color filter and may include a red colorant. The third color filter 323 may include a base resin, and the red colorant may be dispersed in the base resin.

The first color filter 321 may include a first filtering pattern area 321a and a first light blocking pattern area 321b surrounding the first filtering pattern area 321a, the second color filter 322 may include a second filtering pattern area 322a and a second light blocking pattern area 322b surrounding the second filtering pattern area 322a, and the third color filter 323 may include a third filtering pattern area 323a and a third light blocking pattern area 323b surrounding the third filtering pattern area 323a.

Specifically, the first filtering pattern area 321a of the first color filter 321 may be in a first light transmitting area TA1, and the first light blocking pattern area 321b of the first color filter 321 may surround the first filtering pattern area 321a that is in the first light transmitting area TA1, without extending into the second light transmitting area TA2 and the third light transmitting area TA3. The first light blocking pattern area 321b may overlap the light blocking area BA. The second filtering pattern area 322a of the second color filter 322 may be in a second light transmitting area TA2, and the second light blocking pattern area 322b of the second color filter 322 may surround the second filtering pattern area 322a that is in the second light transmitting area TA2 without extending into the first light transmitting area TA1 and the third light transmitting area TA3. The second light blocking pattern area 322b may overlap the light blocking area BA. The third filtering pattern area 323a of the third color filter 323 may overlap a third light transmitting area TA3, and the third light blocking pattern area 323b of the third color filter 323 may surround the third filtering pattern area 323a that is in the third light transmitting area TA3 without extending into the first light transmitting area TA1 and the second light transmitting area TA2. The third light blocking pattern area 323b may overlap the light blocking area BA. In other words, the filtering pattern area of a color filter member 320 may include the first filtering pattern area 321a of the first color filter 321, the second filtering pattern area 322a of the second color filter 322, and the third filtering pattern area 323a of the third color filter 323, and the light blocking pattern portion BM may have a structure in which the first light blocking pattern area 321b of the first color filter 321, the second light blocking pattern area 322b of the second color filter 322, and the third light blocking pattern area 323b of the third color filter 323 are stacked.

The first filtering pattern area 321a of the first color filter 321 may function as a blocking filter that blocks red light and green light. Specifically, the first filtering pattern area 321a may selectively transmit the first light (e.g., blue light) and may block or absorb the second light (e.g., green light) and the third light (e.g., red light).

The second filtering pattern area 322a of the second color filter 322 may function as a blocking filter that blocks blue light and red light. Specifically, the second filtering pattern area 322a may selectively transmit the second light (e.g., green light) and may block or absorb the first light (e.g., blue light) and the third light (e.g., red light).

The third filtering pattern area 323a of the third color filter 323 may function as a blocking filter that blocks blue light and green light. Specifically, the third filtering pattern area 323a may selectively transmits the third light (e.g., red light) and may block or absorb the first light (e.g., blue light) and the second light (e.g., green light).

In some embodiments, the light blocking pattern portion BM may have a structure in which the first light blocking pattern area 321b, the third light blocking pattern area 323b, and the second light blocking pattern area 322b are sequentially stacked in the third direction DR3; however, this is not a limitation of the disclosure. For example, the light blocking pattern portion BM may not be made of the color filters 321, 322, and 323 described above, but may be formed of a separate organic light blocking material through a coating and exposure process of the organic light blocking material. With that understanding, hereinafter, for convenience of explanation, the light blocking pattern will be assumed to have a structure in which the first light blocking pattern area 321b, the third light blocking pattern area 323b, and the second light blocking pattern area 322b are sequentially stacked. The light blocking pattern portion BM may absorb all of the first light, the second light, and the third light through the above-described configuration.

The low refractive layer LR may be disposed on one surface of the color filter layer CFL, for example, on the other side of the color filter layer CFL in the third direction DR3. As the low refractive layer LR has a lower refractive index than a first light transmitting member TPL, a second light transmitting member WCL1, and a third light transmitting member WCL2, which will be described later, the low refractive layer LR may serve to recycle light by inducing total reflection of light traveling from the first light transmitting member TPL, the second light transmitting member WCL1, and the third light transmitting member WCL2 to the low refractive layer LR.

The low refractive layer LR may include an organic material. In some embodiments, a refractive index of the low refractive layer LR may be 1.3 or less. When the refractive index of the low refractive layer LR is 1.3 or less, total reflection of light may sufficiently occur because a difference in refractive index between the low refractive layer LR and the first light transmitting member TPL, the second light transmitting member WCL1, and the third light transmitting member WCL2.

In addition, the low refractive layer LR may serve to compensate for and planarize steps caused by the light blocking pattern areas 321b, 322b, and 323b of the color filter layer CFL. Accordingly, the first capping layer CPL1 disposed on the low refractive layer LR may be flat.

The first capping layer CPL1 may be disposed on one surface of the low refractive layer LR and cover the low refractive layer LR. The first capping layer CPL1 may prevent impurities such as moisture or air permeating into the low refractive layer LR or the color filter layer CFL from the outside from damaging or contaminating the low refractive layer LR and the light blocking pattern portion BM and the filtering pattern area of the color filter member 320.

The first capping layer CPL1 may include an inorganic material. In some embodiments, the first capping layer CPL1 may include an inorganic material such as SiO₂, SiNx, or SiON, and may be formed of a single layer or a multi-layer, but is not limited thereto.

The wavelength conversion layer WCL may be disposed on one surface of the first capping layer CPL1. The wavelength conversion layer WCL may include a bank BK, a first light transmitting member TPL, a second light transmitting member WCL1, a third light transmitting member WCL2, and a second capping layer CPL2.

With reference to FIG. 6, the banks BK may be disposed on the other side of the first capping layer CPL1 in the third direction DR3 and spaced apart from each other in the second direction DR2 to form spaces for accommodating the light transmitting members. That is, the bank BK may serve to partition the space in which the light transmitting members are disposed. The bank BK may be in direct contact with the other side of the first capping layer CPL1 in the third direction DR3. The bank BK may surround the light transmitting members in plan view. The bank BK may be disposed in the non-light emitting area NELA and the light blocking area BA. The bank BK may not be disposed in the light emitting areas ELA1, ELA2, and ELA3 and the light transmitting areas TA1, TA2, and TA3.

In some embodiments, the bank BK may include an organic material that is photocurable or an organic material that is photocurable and includes a light blocking material, but is not limited thereto.

The first light transmitting member TPL may be in the first light transmitting area TA1, the second light transmitting member WCL1 may be in the second light transmitting area TA2, and the third light transmitting member WCL2 may be in the third light transmitting area TA3. Meanwhile, the first light transmitting member TPL, the second light transmitting member WCL1, and the third light transmitting member WCL2 may be referred to as a wavelength conversion layer or a wavelength conversion material layer.

The first light transmitting member TPL may be disposed in the spaces partitioned by the bank BK in the first light emitting area ELA1 and the first light transmitting area TA1. The first light transmitting member TPL may be in direct contact with the first capping layer CPL1 and the bank BK.

The first light transmitting member TPL may be a light transmitting pattern that transmits incident light. The first light transmitting member TPL may directly transmit light of a first color emitted from the light emitting element layer EML. Specifically, the emitted light provided from the first light emitting element is blue light as described above, and may transmit through the first light transmitting member TPL and the first filtering pattern area 321a of the first color filter 321 and be emitted to the outside of the display device 10. In other words, first emitted light L1 that transmits through the first light transmitting area TA1 from the first light emitting area ELA1 and is emitted to the outside may be blue light.

The first light transmitting member TPL may include a base resin 330 and light scatterers 331.

The base resin 330 may be made of an organic material with high light transmittance. In some embodiments, the base resin 330 may include an organic material such as epoxy resin, acrylic resin, cardo resin, or imide resin, but is not limited thereto.

The light scatterer 331 may have a different refractive index from the base resin 330 and form an optical interface with the base resin 330. The light scatterer 331 may be a light scattering particle. The light scatterer 331 may scatter light in a random direction irrespective of an incident direction of the incident light without substantially converting a wavelength of the light transmitted through the first light transmitting area TA1.

The light scatterer 331 may include metal oxide particles or organic particles as a material that scatters at least a portion of transmitted light. In some embodiments, the light scatterers 331 may include titanium oxide (TiO₂), zirconium oxide (ZrO₂), aluminum oxide (Al₂O₃), indium oxide (In₂O₃), zinc oxide (ZnO), tin oxide (SnO₂), or the like as metal oxide, and may include an acrylic resin, a urethane resin, or the like as the organic particles, but is not limited thereto.

The second light transmitting member WCL1 may be disposed in the spaces partitioned by the bank BK in the second light emitting area ELA2 and the second light transmitting area TA2. The second light transmitting member WCL1 may be in direct contact with the first capping layer CPL1 and the bank BK.

The second light transmitting member WCL1 may be a wavelength conversion pattern that converts or shifts a peak wavelength of the incident light to light having another specific peak wavelength and emits the light having another specific peak wavelength. The second light transmitting member WCL1 may convert the light of the first color emitted from the light emitting element layer EML into light of a second color and emit the light of the second color. Specifically, if the emitted light provided from the second light emitting element is blue light as described above, and the blue light may transmit through the second light transmitting member WCL1 and the second filtering pattern area 322a of the second color filter 322, and be converted into green light having a peak wavelength in the range of 510 nm to about 550 nm before being emitted to the outside of the display device 10. In other words, second emitted light L2 that transmits through the second light transmitting area TA2 from the second light emitting area ELA2 and gets emitted to the outside may be green light.

The second light transmitting member WCL1 may include a base resin 330, light scatterers 331 disposed to be dispersed within the base resin 330, and first wavelength shifters 332 disposed to be dispersed within the base resin 330.

The first wavelength shifter 332 may convert or shift the peak wavelength of the incident light into another specific peak wavelength. The first wavelength shifter 332 may convert the emitted light, which is the blue light provided from the second light emitting element, into green light having a single peak wavelength in the range of 510 nm to about 550 nm.

In some embodiments, the first wavelength shifter 332 may be a quantum dot, a quantum rod, or a phosphor, but is not limited thereto. Hereinafter, for convenience of explanation, it will be mainly described that the first wavelength shifter 332 is a quantum dot. The quantum dot may be a particulate material that emits a specific color as electrons transition from a conduction band to a valence band. The quantum dot may be a semiconductor nano-crystal material. The quantum dot may have a specific bandgap according to the composition and size thereof to absorb light and then emit light having a unique wavelength. Examples of the semiconductor nano-crystal of the quantum dot may include group IV nano-crystal, group II-VI compound nano-crystal, group III-V compound nano-crystal, group IV-VI nano-crystal, or a combination thereof.

The group II-VI compound may be selected from the group consisting of a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of InZnP, AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures of thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound may be selected from the group consisting of a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

A group IV-VI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. A group IV element may be selected from the group consisting of Si, Ge, and mixtures thereof. A group IV compound may be a binary compound selected from the group consisting of SiC, SiGe, and mixtures thereof.

Here, the binary compound, the ternary compound, or the quaternary compound may be present in a particle at a uniform concentration or may be present in the same particle in a state of partially different concentration distributions. In addition, the quantum dot may have a core/shell structure in which one quantum dot surrounds another quantum dot. An interface between the core and the shell may have a concentration gradient in which a concentration of the element present in the shell decreases toward the center.

In some embodiments, the quantum dot may have a core-shell structure including a core including the above-described nanocrystals and a shell surrounding the core. The shell of the quantum dot may serve as a protective layer for maintaining semiconductor properties by preventing chemical modification of the core and/or a charging layer for imparting electrophoretic properties to the quantum dot. The shell may be a single layer or a multi-layer. An interface between the core and the shell may have a concentration gradient in which a concentration of the element present in the shell decreases toward the center. Examples of the shell of the quantum dot may include a metal or non-metal oxide, a semiconductor compound, or a combination thereof.

For example, examples of the metal or non-metal oxide may include a binary compound such as SiO₂, Al₂O₃, TiO₂, ZnO, MnO, Mn₂O₃, Mn₃O₄, CuO, FeO, Fc₂O₃, Fe₃O₄, CoO, Co₃O₄, or NiO or a ternary compound such as MgAl₂O₄, CoFe₂O₄, NiFe₂O₄, or CoMn₂O₄, but the present disclosure is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but the present disclosure is not limited thereto.

The light emitted by the first wavelength shifter 332 may have an emission wavelength spectrum full width of half maximum (FWHM) of about 45 nm or less, about 40 nm or less, or about 30 nm or less, and through this, color purity and color reproducibility of colors displayed by the display device 10 may be further improved. In addition, the light emitted by the first wavelength shifter 332 may be emitted in several directions regardless of the incident direction of the incident light. Through this, side visibility of the second color displayed in the second light transmitting area TA2 may be improved.

Some of the emitted light provided from the second light emitting element may not be converted into the green light by the first wavelength shifter 332 and may be emitted by transmitting through the second light transmitting member WCL1. The component among the emitted light whose wavelength is not converted by the second light transmitting member WCL1 and entering the second filtering pattern area 322a of the second color filter 322 may be blocked by the second filtering pattern area 322a. On the other hand, the green light among the emitted light converted by the second light transmitting member WCL1 transmits through the second filtering pattern area 322a and is emitted to the outside. That is, the second emitted light L2 emitted to the outside of the display device 10 through the second light transmitting area TA2 may be the green light.

The third light transmitting member WCL2 may be disposed in the spaces partitioned by the bank BK in the third light emitting area ELA3 and the third light transmitting area TA3. The third light transmitting member WCL2 may be in direct contact with the first capping layer CPL1 and the bank BK.

The third light transmitting member WCL2 may be a wavelength conversion pattern that converts or shifts a peak wavelength of the incident light to light having another specific peak wavelength and emits the light having another specific peak wavelength. Specifically, if the emitted light provided from the third light emitting element is blue light as described above, the blue light may transmit through the third light transmitting member WCL2 and the third filtering pattern area 323a of the third color filter 323, be converted into red light having a peak wavelength in the range of about 610 nm to about 650 nm, and be emitted to the outside of the display device 10. In other words, third emitted light L3 that transmits through the third light transmitting area TA3 from the third light emitting area ELA3 and is emitted to the outside may be red light.

The third light transmitting member WCL2 may include a base resin 330, light scatterers 331 disposed to be dispersed within the base resin 330, and second wavelength shifters 333 disposed to be dispersed within the base resin 330.

The second wavelength shifter 333 may convert or shift the peak wavelength of the incident light into another specific peak wavelength. The second wavelength shifter 333 may convert the emitted light, which is the blue light provided from the third light emitting element, into red light having a single peak wavelength in the range of about 610 nm to about 650 nm and emit the red light. In some embodiments, the second wavelength shifter 333 may be a quantum dot, a quantum rod, or a phosphor, but is not limited thereto. When the second wavelength shifter 333 is a quantum dot, it has substantially the same configuration as when the first wavelength shifter 332 is the quantum dot as described above. Hence, any redundant description will be omitted.

Some of the emitted light provided from the third light emitting element may not be converted into the red light by the second wavelength shifter 333 and may be emitted by being transmitted through the third light transmitting member WCL2. The component of the emitted light that enters the third filtering pattern area 323a of the third color filter 323 without being converted by the third light transmitting member WCL2 may be blocked by the third filtering pattern area 323a. On the other hand, the red light component of the emitted light converted by the third light transmitting member WCL2 transmits through the third filtering pattern area 323a and is emitted to the outside. That is, the third light L3 emitted to the outside of the display device 10 through the third light transmitting area TA3 may be the red light.

The second capping layer CPL2 may be disposed on the bank BK, the first light transmitting member TPL, the second light transmitting member WCL1, and the third light transmitting member WCL2, and to prevent impurities such as moisture or air from the outside from damaging or contaminating the first light transmitting member TPL, the second light transmitting member WCL1, and the third light transmitting member WCL2. The second capping layer CPL2 may cover the first light transmitting member TPL, the second light transmitting member WCL1, and the third light emitting member WCL2.

The spacer layer SPC may be disposed on one surface of the second capping layer CPL2. The spacer layer SPC may maintain a cell gap between the substrate SUB and the counter substrate TSUB. The spacer layer SPC may surround the light transmitting members in plan view. The spacer layer SPC may be disposed in the non-light emitting area NELA and the light blocking area BA. The spacer layer SPC may not be in the light emitting areas ELA1, ELA2, and ELA3 and the light transmitting areas TA1, TA2, and TA3.

In some embodiments, the spacer layer SPC may include a transparent organic material that is photocurable or an organic material that is photocurable and includes a light blocking material, but is not limited thereto. In some embodiments, the spacer layer SPC may be made of an acrylic resin, a methacrylic resin, polyisoprene, a vinyl resin, an epoxy resin, a urethane resin, a cellulose resin, a perylene resin, or the like, but is not limited thereto.

A filling layer FIL may be disposed between the counter substrate TSUB and the substrate SUB. The filling layer FIL may be interposed between the wavelength conversion layer WCL and the thin film encapsulation layer TFEL to fill a space between the wavelength conversion layer WCL and the thin film encapsulation layer TFEL. Specifically, in some embodiments, the filling layer FIL may be in direct contact with the upper inorganic layer TFE3 of the thin film encapsulation layer TFEL and the second capping layer CPL2 of the wavelength conversion layer WCL. However, this is not a limitation of the disclosure.

In some embodiments, the filling layer FIL may be made of a material having an extinction coefficient of substantially zero. There is a correlation between the refractive index and the extinction coefficient, and as the refractive index decreases, the extinction coefficient also decreases. In addition, when the refractive index is 1.7 or less, the extinction coefficient may substantially converge to zero. In some embodiments, the filling layer FIL may be made of a material having a refractive index of 1.7 or less, and accordingly, it is possible to prevent or minimize light provided from the self-light emitting element from being absorbed while passing through the filling layer FIL. In some embodiments, the filling layer FIL may be made of an organic material having a refractive index of 1.4 to 1.6.

The organic layer TFE2 of the thin film encapsulation layer TFEL may be applied on the substrate SUB through a solution process, as will be described later. For example, the organic layer TFE2 may be applied on the substrate SUB through an inkjet printing method. The organic layer TFE2 may fill the step formed by the pixel defining film 170 and planarize the upper portion. When the spreadability of the organic layer TFE2 is low when applying the organic layer TFE2, stains due to the organic layer TFE2 not spreading may be recognized by an end user of the display device because the organic layer TFE2 does not fill the above-mentioned step.

Therefore, the present inventors disclose a method for manufacturing an organic layer composition capable of improving spreadability of the organic layer TFE2 through a process of manufacturing the organic layer material that affects the spreadability of the organic layer TFE2, and a method for manufacturing a display device using the same.

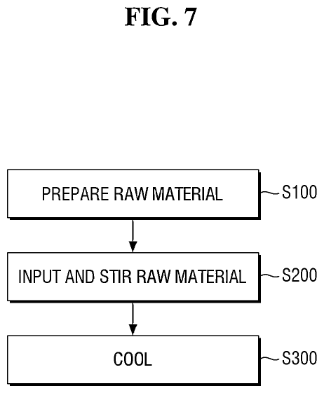

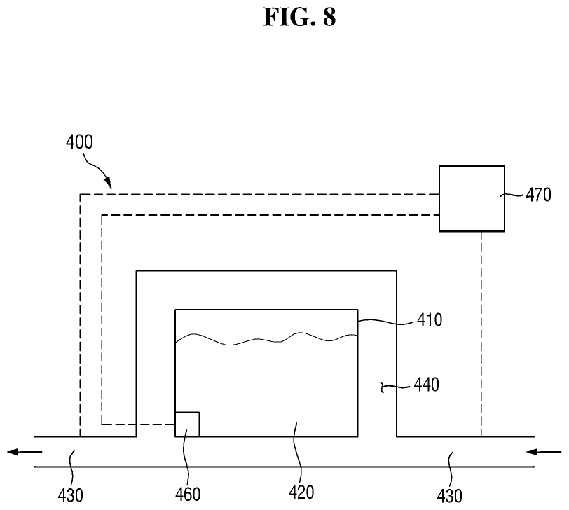

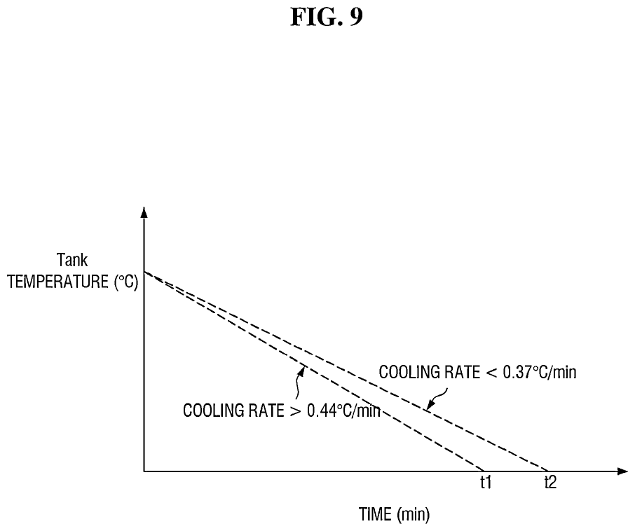

FIG. 7 is a flowchart schematically illustrating a method for manufacturing an organic layer composition according to an embodiment. FIG. 8 is a view schematically illustrating a device for manufacturing an organic layer composition. FIG. 9 is a graph illustrating a temperature of a tank of the manufacturing device over time.

Referring to FIG. 7, a method for manufacturing an organic layer composition may include a raw material preparation step (S100), a raw material input and stirring step (S200), and a cooling step (S300).

The raw material preparation step (S100) may be a step in which a raw material for manufacturing the organic layer composition is prepared. The organic layer composition may include a monomer, an initiator, and a solvent.

The monomer may include an acrylic compound or an epoxy compound. For example, the monomer may include an acrylic compound, and the acrylic compound may be acrylate. Examples of the acrylate may include, for example, 1,4-butanediol di(meth)acrylate, 1,3-butylene glycol di(meth)acrylate, 1,6-hexanediol di(meth)acrylate, 1,8-octanediol di(meth)acrylate, 1,9-octanediol diacrylate, 1,12-dodecanediol di(meth)acrylate, ethylene glycol di(meth)acrylate, propylene glycol di(meth)acrylate, tripropylene glycol di(meth)acrylate, polyolefin glycol di(meth)acrylate, polyethylene glycol di(meth)acrylate, ethoxylated polypropylene glycol di(meth)acrylate, neopentyl glycol di(meth)acrylate, 2-hydroxy-1,3-dimethacryloxypropane, dioxane glycol di(meth)acrylate, glycerin di(meth)acrylate, 1,9-nonanediol di(meth)acrylate, 1,10-decanediol di(meth)acrylate, 2-methyl-1,8-octanediol di(meth)acrylate, 1,9-nonanediol di(meth)acrylate, 1,12-dodecane di(meth)acrylate, butyl ethyl propanediol di(meth)acrylate, 3-methyl-1,5-pentanediol di(meth)acrylate, dicyclopentanyl di(meth)acrylate, cyclohexane-1,4-dimethanol di(meth)acrylate, tricyclodecanedimethanol di(meth)acrylate, dimethylol dicyclopentane di(meth)acrylate, neopentyl glycol modified trimethylpropane di(meth)acrylate, and adamantane di(meth)acrylate, but are not limited thereto.

The monomer may be included in an amount of 10 to 50 parts by weight based on the total weight of the organic layer composition. When the monomer satisfies the above-mentioned range, the monomer may have excellent photo-curing rate.

The initiator may include a photo-initiator or a photo-initiator and a thermal initiator. The photo-initiator may be activated in a wavelength band of 360 nm to 400 nm (e.g., UV wavelength band). The photo-initiator may include, for example, an oxime-based compound, an acetophenone-based compound, a thioxanthone-based compound, a benzophenone-based compound, or a combination thereof.

The oxime-based compound may include, for example, 1,2-octanedione, 2-dimethylamino-2-(4-methylbenzyl)-1-(4-morpholin-4-yl-phenyl)-butan-1-one, 1-(4-phenyl sulfanylphenyl)-butane-1,2-dione-2-oxime-O-benzoate, 1-(4-phenyl sulfanylphenyl)-octane-1,2-dione-2-oxime-O-benzoate, 1-(4-phenyl sulfanylphenyl)-octane-1-one oxime-O-acetate, 1-(4-phenyl sulfanylphenyl)-butan-1-one-2-oxime-O-acetate, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, or a combination thereof.

The acetophenone-based compound may include, for example, 4-phenoxy dichloroacetophenone, 4-t-butyl dichloroacetophenone, 4-t-butyl trichloroacetophenone, 2,2-diethoxyacetophenone, 2-hydroxy-2-methyl-1-phenyl-propan-1-one, 1-(4-isopropylphenyl)-2-hydroxy-2-methyl-propan-1-one, 1-(4-dodecylphenyl)-2-hydroxy-2-methylpropan-1-one, 4-(2-hydroxyethoxy)-phenyl-(2-hydroxy-2-propyl) ketone, 1-hydroxycyclohexyl phenyl ketone and 2-methyl-1-[4-(methylthio)phenyl]-2-morpholino-propan-1-one, or a combination thereof.

The thioxanthone-based compound may include, for example, thioxanthone, 2-chlorothioxanthone, 2-methylthioxanthone, isopropyl thioxanthone, 2,4-diethyl thioxanthone, and 2,4-diiso propyl thioxanthone, or a combination thereof.

The benzophenone-based compound may include, for example, benzophenone, benzoyl benzoic acid, benzoyl benzoic acid methyl ester, 4-phenyl benzophenone, hydroxybenzophenone, 4-benzoyl-4′-methyl diphenyl sulfide and 3,3′-dimethyl-4-methoxy benzophenone, or a combination thereof.

The thermal initiator may be a material that is activated by heat. The thermal initiator may include, for example, azo compounds such as 2,2′-azobis(2-methylbutyronitrile), 2,2′-azobis(isobutyronitrile), 2,2′-azobis(2,4-dimethylvaleronitrile), 4,4-azobis(4-cyanovaleric acid), 1,1′-azobis(cyclohexanecarbonitrile), and 2,2′-azobis(4-methoxy-2,4-dimethylvaleronitrile), peroxy compounds such as tetramethylbutylperoxy neodecanoate, bis(4-butylcyclohexyl) peroxydicarbonate, di(2-ethylhexyl) peroxy carbonate, butyl peroxy neodecanoate, dipropyl peroxy dicarbonate, diisopropyl peroxy dicarbonate, diethoxyethyl peroxy dicarbonate, diethoxyhexyl peroxy dicarbonate, hexyl peroxy dicarbonate, dimethoxybutyl peroxy dicarbonate, bis(3-methoxy-3-methoxybutyl) peroxy dicarbonate, dibutyl peroxy dicarbonate, dicetyl peroxy dicarbonate, dimyristyl peroxy dicarbonate, 1,1,3,3-tetramethylbutyl peroxypivalate, hexyl peroxy pivalate, butyl peroxy pivalate, trimethyl hexanoyl peroxide, dimethyl hydroxybutyl peroxy neodecanoate, amyl peroxyneodecanoate, butyl peroxyncodecanoate, t-butylperoxy neoheptanoate, amyl peroxy pivalate, t-butyl peroxy pivalate, t-amyl peroxy-2-ethylhexanoate, lauryl peroxide, dilauroyl peroxide, didecanoyl peroxide, benzoyl peroxide, dibenzoyl peroxide, 2,2-bis(tert-butylperoxy) butane, 1,1-bis(tert-butylperoxy)cyclohexane, 2,5-bis(butylperoxy)-2,5-dimethylhexane, 2,5-bis(tert-butylperoxy)-1-methyl ethyl)benzene, 1,1-bis(tert-butylperoxy)-3,3,5-trimethylcyclohexane, tert-butyl hydroperoxide, tert-butyl peroxide, tert-butyl peroxybenzoate, tert-butylperoxy isopropyl carbonate, cumene hydroxyperoxide, dicumyl peroxide, lauroyl peroxide, or 2,4-pentanedione peroxide; tert-butyl peracetate; peracetic acid or potassium persulfate, or a combination thereof.

The initiator may be included in an amount of 1 to 5 parts by weight based on the total weight of the organic layer composition. When the content of the initiator satisfies the above-mentioned range, a polymerization reaction of the organic layer composition may be sufficiently performed.

The solvent may be a material having compatibility with the monomer and the initiator, but not reacting with them.

The solvent may be, for example, a compound of alcohols such as methanol and ethanol; ethers such as dichloroethyl ether, n-butyl ether, diisoamyl ether, methylphenyl ether and tetrahydrofuran; glycol ethers such as ethylene glycol methyl ether, ethylene glycol ethyl ether and propylene glycol methyl ether; cellosolve acetates such as methyl cellosolve acetate, ethyl cellosolve acetate and diethyl cellosolve acetate; carbitols such as methylethyl carbitol, diethyl carbitol, diethylene glycol monomethyl ether, diethylene glycol monoethyl ether, diethylene glycol dimethyl ether, diethylene glycol methyl ethyl ether and diethylene glycol diethyl ether; propylene glycol alkyl ether acetates such as propylene glycol methyl ether acetate, propylene glycol monoethyl ether acetate and propylene glycol propyl ether acetate; aromatic hydrocarbons such as toluene and xylene; ketones such as methyl ethyl ketone, cyclohexanone, 4-hydroxy-4-methyl-2-pentanone, methyl-n-propyl ketone, methyl-n-butyl ketone, methyl-n-amyl ketone and 2-heptanone; saturated aliphatic monocarboxylic acid alkyl esters such as ethyl acetate, n-butyl acetate and isobutyl acetate; lactic acid alkyl esters such as methyl lactate and ethyl lactate; hydroxyacetic acid alkyl esters such as methyl hydroxyacetate, ethyl hydroxyacetate and butyl hydroxyacetate; acetic acid alkoxyalkyl esters such as methoxymethyl acetate, methoxyethyl acetate, methoxybutyl acetate, ethoxymethyl acetate and ethoxyethyl acetate; 3-hydroxypropionic acid alkyl esters such as methyl 3-hydroxypropionate and ethyl 3-hydroxypropionate; 3-alkoxypropionic acid alkyl esters such as methyl 3-methoxypropionate, ethyl 3-methoxypropionate, ethyl 3-ethoxypropionate and methyl 3-ethoxypropionate; 2-hydroxypropionic acid alkyl esters such as methyl 2-hydroxypropionate, ethyl 2-hydroxypropionate and propyl 2-hydroxypropionate; 2-alkoxypropionic acid alkyl esters such as methyl 2-methoxypropionate, ethyl 2-methoxypropionate, ethyl 2-ethoxypropionate and methyl 2-ethoxypropionate; 2-hydroxy-2-methylpropionic acid alkyl esters such as methyl 2-hydroxy-2-methylpropionate and ethyl 2-hydroxy-2-methylpropionate; 2-alkoxy-2-methylpropionic acid alkyl esters such as methyl 2-methoxy-2-methylpropionate and ethyl 2-ethoxy-2-methylpropionate; esters such as 2-hydroxyethyl propionate, 2-hydroxy-2-methylethyl propionate, hydroxyethyl acetate and methyl 2-hydroxy-3-methylbutanoate; or ketonic acid esters such as ethyl pyruvate. The solvent may include N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetylacetone, isophorone, caproic acid, caprylic acid, 1-octanol, 1-nonanol, benzyl alcohol, benzyl acetate, benzoic acid ethyl, diethyl oxalate, diethyl maleate, γ-butyrolactone, ethylene carbonate, propylene carbonate, phenyl cellosolve acetate, or a combination thereof.

The solvent may be an amount of 50 to 98 parts by weight based on the total weight of the organic layer composition. In this case, as the organic layer composition has an appropriate viscosity, processability may be excellent.

The organic layer composition may further include other monomers in addition to the monomer, initiator, and solvent. In addition, the organic layer composition may further include additives as needed. Examples of the additives may include, for example, light stabilizer, cross-linking agent, antioxidant, chain transfer agent, photosensitizer, polymerization inhibitor, leveling agent, surfactant, adhesion imparting agent, plasticizer, ultraviolet absorber, storage stabilizer, antistatic agent, inorganic filler, pigment, dye, etc., but are not limited thereto.

Referring to FIGS. 7 and 8, the prepared raw material is then input into a manufacturing device 400 and stirred (S200).

The manufacturing device 400 may include a tank 410 containing the raw material 420, a flow path 440 surrounding the tank 410, an inlet 430 for introducing coolant into the flow path 440, an outlet 450 for discharging the coolant, a thermometer 460 for sensing a temperature in the tank 410, and a controller 470.

The raw material 420 may be input into the tank 410 and the tank 410 may stir the raw material 420. The tank 410 may include a stirrer capable of stirring the raw material 420, thereby stirring the raw material 420. Although not illustrated, a heating device, for example, a heating line, may be disposed in the tank 410 to heat the tank 410 so that the raw material 420 in the tank 410 may be stirred and polymerized.

The flow path 440 may be disposed to surround the tank 410. The flow path 440 may be a passage through which the coolant supplied through the inlet 430 flows. The inlet 430 may be disposed at one end of the flow path 440 and the outlet 450 may be disposed at the other end of the flow path 440. Therefore, when coolant is introduced from the inlet 430, the coolant may be discharged to the outlet 450 through the flow path 440.

The thermometer 460 can measure the temperature inside the tank 410. The thermometer 460 may measure a temperature of the raw material 420 inside the tank 410 and monitor a temperature during stirring and cooling of the raw material 420. The thermometer 460 may be disposed outside the tank 410 for observation by a user. The thermometer 460 may be connected to the controller 470 and transmit the measured temperature to the controller 470.

The controller 470 may be provided outside the tank 410. The controller 470 may automatically adjust a temperature and flow rate of the coolant according to a temperature value input from the thermometer 460 to control a manufacturing temperature of the organic layer composition. The controller 470 may be a Proportional Integral Derivative (PID) controller.

The organic layer composition is manufactured by inputting the prepared raw material 420 in the manufacturing device 400 configured as above and stirring the input raw material 420. In the manufacturing device 400, the raw material 420 may be stirred by setting a stirring temperature through the controller 470 to manufacture the organic layer composition. For example, the stirring temperature may be about 40° C. to 60° C., but is not limited thereto.

Next, the organic layer composition manufactured in the manufacturing device 400 is cooled (S300).

In the cooling step of the organic layer composition, the temperature of the organic layer composition may be lowered to room temperature. For example, when the temperature of the organic layer composition manufactured after completion of stirring is about 40° C., the temperature of the organic layer composition may be cooled to room temperature (e.g., 25° C.).

The cooling step may be performed via the controller 470. When a target temperature and a cooling rate are input to the controller 470, the controller 470 may determine the temperature value input through the thermometer 460 and adjust the temperature and flow rate of the coolant.

In an embodiment, when cooling the organic layer composition, the cooling rate may be in the range of 0.37° C./min to 0.44° C./min.

When the organic layer composition is applied on the substrate, defects occur if spreadability of the organic layer composition is low. The present inventors found that the cooling rate of the organic layer composition affects the spreadability.

Referring to FIG. 9, if the cooling rate of the organic layer composition exceeded 0.44° C./min, impact defects occurred when the organic layer composition was applied using an inkjet printing method. In addition, if the cooling rate of the organic layer composition is less than 0.37° C./min, the spreadablity of the organic layer composition on the substrate decreases, resulting in defects such as spots being visible on the display device.

The defects are due to a phenomenon by which crystalline materials at room temperature among the monomers of the organic layer composition recrystallize as a cooling time of the organic layer composition increases. Accordingly, an unstable dissolution state of a solid component occurs, which reduces the spreadability of the organic layer composition during inkjet printing. In addition, during the stirring process of the raw material, the photo-initiator forms dynamic covalent bonds with impurities, thereby increasing a molecular weight, which in turn increases a viscosity of the organic layer composition and reduces the spreadability.

Therefore, in the present embodiment, as the organic layer composition is cooled at the cooling rate in the range of 0.37° C./min to 0.44° C./min, the quality of the display device may be improved by preventing a decrease in the spreadability of the organic layer composition. The enhanced spreadability of the organic layer composition reduces defects during inkjet printing.

Hereinafter, a method for manufacturing a display device using the organic layer composition manufactured according to the method for manufacturing the organic layer composition described above will be described.

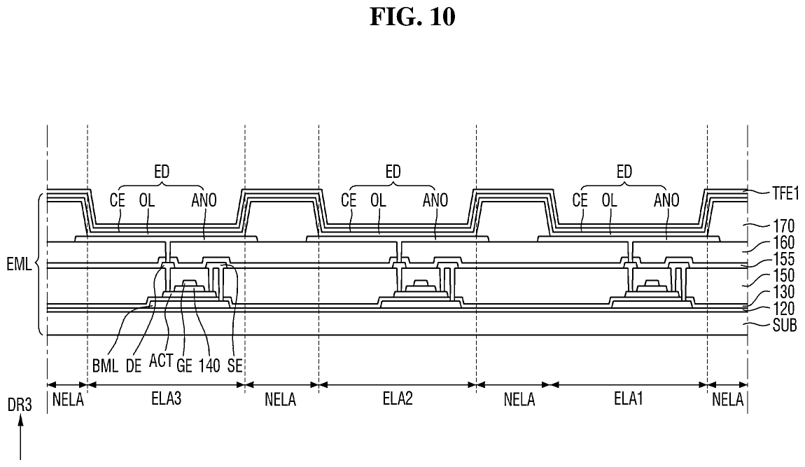

FIGS. 10 to 12 are cross-sectional views illustrating a method for manufacturing a display device according to an embodiment. FIGS. 10 to 12 illustrate a method for manufacturing a display device up to the thin film encapsulation layer TFEL including the organic layer TFE2.

First, referring to FIG. 10, a light emitting element layer EML is formed on the substrate SUB.

Specifically, a buffer layer 120, a lower metal layer BML, a first insulating layer 130, a semiconductor layer ACT, a gate electrode GE, a gate insulating layer GI, a second insulating layer 150, a source electrode SE, a drain electrode DE, a third insulating layer 155, a fourth insulating layer 160, a light emitting element ED, and a pixel defining film 170 are formed on the substrate SUB.

The lower metal layer BML, the semiconductor layer ACT, the gate electrode GE, and the source electrode SE, the drain electrode DE and the pixel electrode ANO of the light emitting element ED disposed on the substrate SUB may be formed by depositing a material forming each layer, such as a metal material, and patterning the material using a mask. In addition, the buffer layer 120, the first insulating layer 130, the gate insulating layer GI, the second insulating layer 150, the third insulating layer 155, the fourth insulating layer 160, and the pixel defining film 170 disposed on the substrate SUB may be formed by applying a material forming each layer, such as an insulating material, or, if necessary, through a patterning process using a mask. A description of the structure of the plurality of layers disposed on the substrate SUB is the same as that described above. Hence, any redundant description will be omitted.

In an embodiment, with respect to the light emitting element ED, a pixel electrode ANO is formed on the fourth insulating layer 160, and the pixel defining film 170 covering an edge of the pixel electrode ANO is formed. Thereafter, the light emitting element ED may be manufactured by forming a light emitting layer OL on the pixel electrode ANO and the pixel defining film 170, and forming a common electrode CE on the light emitting layer OL.

Next, a lower inorganic layer TFE1 of a thin film encapsulation layer TFEL is formed on the light emitting element layer EML. The lower inorganic layer TFE1 may be formed directly on the common electrode CE of the light emitting element layer EML.

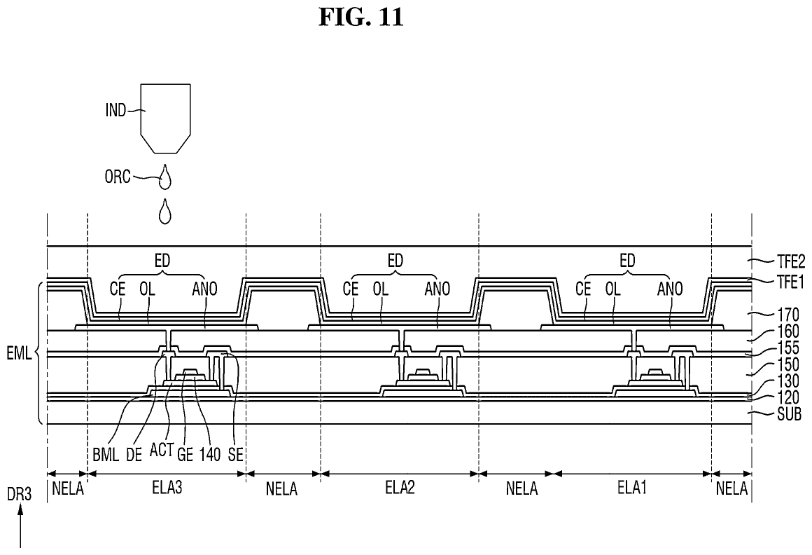

Next, referring to FIG. 11, an organic layer TFE2 is formed on the substrate SUB on which the lower inorganic layer TFEL is formed.

The organic layer TFE2 may use the organic layer composition ORC described above with reference to FIGS. 7 to 9. The organic layer composition ORC may be manufactured by stirring and cooling a raw material. In an embodiment, the organic layer composition ORC may be cooled at a cooling rate in the range of 0.37° C./min to 0.44° C./min.

The organic layer may be formed by applying the organic layer composition using an inkjet printing method. For example, the organic layer composition ORC may be applied on the substrate SUB using an inkjet printing device IND. As the organic layer composition ORC is cooled at the cooling rate in the above-mentioned range, the quality of the display device may be improved by reducing impact defects and improving spreadability during inkjet printing.

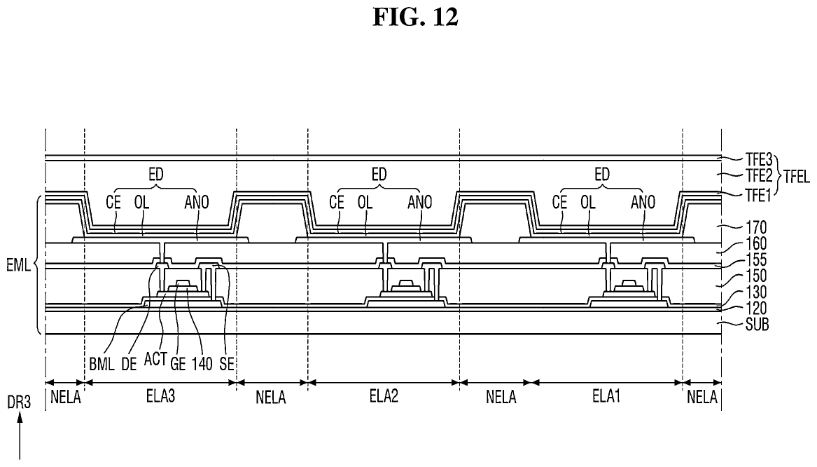

Next, referring to FIG. 12, a thin film encapsulation layer TFEL is manufactured by stacking an upper inorganic layer TFE3 on the organic layer TFE2. Next, although not illustrated, the display device is manufactured by forming a color filter layer CFL, a wavelength conversion layer WCL, and a filling layer FIL on the counter substrate TSUB and bonding them with the substrate SUB as illustrated in FIG. 6.

Hereinafter, an experimental example of the method for manufacturing the organic layer composition described above and the display device manufactured using the same will be disclosed.

### Manufacturing Example

An organic layer composition was manufactured using the same organic layer composition at different cooling rates of 0.45° C./min, 0.41° C./min, 0.42° C./min, and 0.35° C./min, respectively, and the display devices illustrated in FIG. 6 were manufactured using such an organic layer composition.

### Experimental Examples

Impact defects and stain defects of the display devices were actually measured, and the results of AI prediction using a confusion matrix are shown in Table 1 below.

TABLE 1

| | Cooling Rate (° C./min) | | | |
|---|---|---|---|---|
| Classification | 0.45 | 0.41 | 0.42 | 0.35 |
| AI Prediction | Impact Defect | OK | OK | Stain Defect |
| Actual Measurement | Impact Defect | OK | OK | Stain Defect |

Referring to Table 1, the display device manufactured with the organic layer composition manufactured at the cooling rate of 0.45° C./min had impact defects in both AI prediction and actual measurement. The display device manufactured with the organic layer composition manufactured at the cooling rate of 0.35° C./min had stain defects in both AI prediction and actual measurement. On the other hand, the display devices manufactured with the organic layer compositions manufactured at the cooling rates of 0.41° C./min and 0.42° C./min had no defects in both AI predictions and actual measurements.

Through these results, it was confirmed that the organic layer composition manufactured by cooling at the cooling rate in the range of 0.37° C./min to 0.44° C./min was able to prevent impact and stain defects in the display device.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A method for manufacturing an organic layer composition, the method comprising:
preparing a raw material;
forming an organic layer composition by placing the raw material in a manufacturing device and stirring the raw material; and
cooling the organic layer composition at a cooling rate of 0.37 to 0.44° C./min.

2. The method of claim 1, wherein the raw material includes a monomer, an initiator and a solvent.

3. The method of claim 2, wherein the monomer is an acrylic or epoxy monomer.

4. The method of claim 2, wherein the initiator includes a photo-initiator or a combination of a photo-initiator and a thermal initiator.

5. The method of claim 1, wherein the manufacturing device includes:
a tank containing the raw material;
a flow path surrounding the tank;
an inlet introducing coolant into the flow path;
an outlet through which the coolant is discharged from the flow path;
a thermometer disposed outside the tank and sensing a temperature within the tank; and
a controller disposed outside the tank.

6. The method of claim 5, wherein the inlet is disposed at one end of the flow path, and the outlet is disposed at the other end of the flow path.

7. The method of claim 5, wherein the controller receives the temperature from the thermometer and controls a temperature and a flow rate of the coolant.

8. The method of claim 5, wherein the controller is a Proportional Integral Derivative (PDI) controller.

9. The method of claim 1, wherein the organic layer composition is cooled to 25° C.

10. A method for manufacturing a display device, the method comprising:
forming a light emitting element layer including a light emitting element on a substrate;
forming a lower inorganic layer on the light emitting element layer;
forming an organic layer by applying an organic layer composition on the lower inorganic layer; and
forming an upper inorganic layer on the organic layer,
wherein the organic layer composition is manufactured by:
preparing a raw material;
forming an organic layer composition by inputting the raw material to a manufacturing device and stirring the raw material; and
cooling the organic layer composition at a cooling rate of 0.37 to 0.44° C./min.

11. The method of claim 10, wherein the forming of the light emitting element layer includes:
forming a pixel electrode on the substrate;
forming a pixel defining film covering an edge of the pixel electrode;
forming a light emitting layer on the pixel electrode and the pixel defining film; and
forming a common electrode on the light emitting layer.

12. The method of claim 11, wherein forming the lower inorganic layer comprises forming the lower inorganic layer on the common electrode of the light emitting element layer.

13. The method of claim 10, wherein applying the organic layer composition comprises using an inkjet printing method.

14. The method of claim 10, wherein the raw material includes a monomer, an initiator and a solvent.

15. The method of claim 14, wherein the monomer is an acrylic or epoxy monomer.

16. The method of claim 10, wherein the manufacturing device includes:
a tank containing the raw material;
a flow path surrounding the tank;
an inlet introducing coolant into the flow path;
an outlet through which the coolant is discharged from the flow path;
a thermometer disposed outside the tank and sensing a temperature within the tank; and
a controller disposed outside the tank.

17. The method of claim 16, wherein the inlet is disposed at one end of the flow path, and the outlet is disposed at the other end of the flow path.

18. The method of claim 16, wherein the controller receives the temperature from the thermometer and controls a temperature and a flow rate of the coolant.

19. The method of claim 16, wherein the controller is a Proportional Integral Derivative (PDI) controller.

20. The method of claim 10, wherein the organic layer composition is cooled to 25° C.
